(19) United States
(12) Patent Application Publication
(10) Pub. No.: US 2026/0110576 A1
(43) Pub. Date: Apr. 23, 2026

(54) METHOD FOR PERFORMANCE EVALUATION AND STRUCTURE OPTIMIZATION OF HIGH-POWER SEMICONDUCTOR LASER CHIP, AND SYSTEM FOR PERFORMANCE EVALUATION

(71) Applicants: SUZHOU EVERBRIGHT PHOTONICS CO., LTD., Suzhou (CN); EVERBRIGHT INSTITUTE OF SEMICONDUCTOR PHOTONICS CO., LTD., Suzhou (CN)

(72) Inventors: Jun Wang, Suzhou (CN); Wuling Liu, Suzhou (CN); Shaoyang Tan, Suzhou (CN); Ye Shao, Suzhou (CN); Quanling Li, Suzhou (CN); Dayong Min, Suzhou (CN)

(73) Assignees: SUZHOU EVERBRIGHT PHOTONICS CO., LTD., Suzhou (CN); EVERBRIGHT INSTITUTE OF SEMICONDUCTOR PHOTONICS CO., LTD., Suzhou (CN)

(21) Appl. No.: 19/148,709

(22) PCT Filed: Mar. 7, 2025
(86) PCT No.: PCT/CN2025/081365

§ 371 Date: Jul. 17, 2025

(30) Foreign Application Priority Data
Apr. 30, 2024 (CN) 202410534321.3

(51) Int. Cl. G01J 5/00; G01R 31/311; G06T 7/00

(52) U.S. Cl. CPC G01J 5/0007; G01R 31/311; G06T 7/0004; G06T 2207/30148

(57) ABSTRACT

The present application provides a method for performance evaluation and structure optimization of a high-power semiconductor laser chip, and a system for performance evaluation. Wherein the method for performance evaluation of a high-power semiconductor laser chip comprises: setting a window in an N-surface electrode of a chip to be tested; maintaining the chip to be tested in an operating state, wherein spontaneous radiation is generated in an active area of a quantum well of the chip to be tested; imaging the spontaneous radiation at a position outside the chip to be tested; acquiring, by using a spectrometer outside the chip to be tested, a spectrum of the spontaneous radiation to obtain a two-dimensional distribution of temperature of the quantum well of the chip to be tested in the operating state; and acquiring, by using a CCD camera outside the chip to be tested, an image of the spontaneous radiation to obtain a two-dimensional distribution of carriers in the quantum well of the chip to be tested in the operating state. The method for performance evaluation and structure optimization of a high-power semiconductor laser chip provided by the present application can get the temperature distribution and the carrier concentration distribution of the chip to be tested in the operating state with a resolution that is freely adjustable, the operation is convenient and easy to implement, and the accuracy of evaluation results is effectively improved.

### RELATED APPLICATIONS

The present application claims priority to Chinese Patent Application No. 202410534321.3, filed to the China National Intellectual Property Administration (CNIPA) on Apr. 30, 2024, and entitled “METHOD FOR PERFORMANCE EVALUATION AND STRUCTURE OPTIMIZATION OF HIGH-POWER SEMICONDUCTOR LASER CHIP”, the entire content of which is incorporated herein by reference.

### TECHNICAL FIELD

The present application relates to the technical field of semiconductor lasers, and in particular relates to a method for performance evaluation and structure optimization of a high-power semiconductor laser chip, and a system for performance evaluation.

### BACKGROUND

The development trend of high-power semiconductor laser chips is higher power conversion efficiency, higher output optical power, and higher brightness. For a high-power semiconductor laser chip, which is a highly nonlinear system in which photons, carriers, phonons and etc. are coupled with each other, it is very important to obtain the spatial distribution of carriers and temperature within the active area of the laser chip in an operating state, for performance evaluation of the laser chip and targeted structural optimization thereof.

At present, main ways to improve the optical power include increasing a width of the light-emitting area of the laser chip, lengthening a resonance length of the laser chip, and manufacturing a semiconductor laser chip with a wide waveguide area and a long cavity length. A physical size of a high-power wide-waveguide-area long-cavity semiconductor laser in the slow-axis (lateral) direction is much greater than typical operating wavelengths (0.8 to 2.0 μm) thereof. In an operating state with a high electric current, the high-power wide-waveguide-area long-cavity semiconductor laser tends to emit light in multiple modes in the lateral direction due to combined effects of carriers and thermal lateral diffusion, which adversely affects the power efficiency and substantially reduces the lateral beam quality thereof. Due to an extreme asymmetric coating in a cavity length (vertical) direction, there is an inhomogeneous distribution of carrier concentration and temperature along a direction from a high reflective coating to an anti-reflective coating, and especially in an operation state with a high electric current far away from a threshold, the degree of inhomogeneous distribution of carriers and temperature gradually increases, and the performance of the semiconductor laser chip gradually degrades, and the optical output power gradually decreases. These effects would limit further application of the high-power wide-waveguide-area long-cavity semiconductor lasers. Therefore, in order to optimize the structure of high-power wide-waveguide-area long-cavity semiconductor laser chips and further improve the output optical power, the power conversion efficiency and the brightness thereof, it is very important to obtain the temperature distribution and carrier distribution in the active area thereof in a real operating state.

At present, there are some methods that attempt to evaluate the temperature distribution and carrier distribution, including a reflection method to infer the temperature by measuring a reflectivity of the cavity surface, a thermal radiation method by imaging in the mid-infrared and far-infrared band, a method to infer the carrier concentration by measuring spontaneous radiation from a lateral side, and etc. However, these methods suffer from problems such as an insufficient resolution of the test system, difficulty in obtaining two-dimensional distributions of physical quantities within the active area, the test system being cumbersome, and etc.

### SUMMARY OF THE INVENTION

In order to solve one or more of the above-mentioned technical problems, the present application provides a method for performance evaluation and structure optimization of a high-power semiconductor laser chip, and a system for performance evaluation.

With regard to a first aspect of the present application, a method for performance evaluation of a high-power semiconductor laser chip is provided and comprises:
setting a window in an N-surface electrode of a chip to be tested;
maintaining the chip to be tested in an operating state, wherein spontaneous radiation is generated in an active area of a quantum well of the chip to be tested;
imaging the spontaneous radiation at a position outside the chip to be tested by using a first lens pre-set in a radiation path of the spontaneous radiation;
acquiring, by using a spectrometer outside the chip to be tested, a spectrum of the spontaneous radiation to obtain a two-dimensional distribution of temperature of the quantum well of the chip to be tested in the operating state; and
acquiring, by using a CCD camera outside the chip to be tested, an image of the spontaneous radiation to obtain a two-dimensional distribution of carriers in the quantum well of the chip to be tested in the operating state.

With regard to a second aspect of the present application, a method for structure optimization of a high-power semiconductor laser chip is provided and comprises:
obtaining a carrier distribution of the chip to be tested and a light field distribution of the chip to be tested, and recording a current value of the number of longitudinal segments of an N-surface electrode of the chip to be tested as W;
normalizing the light field distribution of the chip to be tested to obtain a normalized light field intensity, recorded as P(z);
normalizing the carrier distribution of the chip to be tested to obtain a normalized carrier intensity, recorded as N(z);
calculating a mismatch degree δ based on the normalized carrier intensity N(z) and the normalized light field intensity P(z), wherein an expression formula of the mismatch degree δ is as follows:

$$δ = {\int }_{0}^{1} ( N ( z ) - P ( z ) ) dz$$

where z represents a normalized longitudinal position:
determining whether the chip to be tested needs to be optimized according to a current value of the mismatch degree δ, and if it is determined that the chip to be tested needs to be optimized, increasing the number of segments of the N-surface electrode of the chip to be tested, so that W=W+1, and changing an arrangement of gold wires on each segment of the N-surface electrode, so that the number of gold wires on each segment of the N-surface electrode is directly proportional to the normalized light field intensity on each segment;
repeatedly performing the above steps until it is determined that the chip to be tested does not need to be optimized according to the mismatch degree δ, and ending the optimization;
wherein the carrier distribution of the chip to be tested is obtained by the aforementioned method for performance evaluation of a high-power semiconductor laser chip.

With regard to a third aspect of the present application, a system for performance evaluation of a high-power semiconductor laser chip is provided, applying the aforementioned method for performance evaluation of a high-power semiconductor laser chip, and the system comprises:
a thermostatic device, configured to maintain a temperature of the chip to be tested so that the chip to be tested is able to operate at a predetermined temperature;
a lens device, comprising a first lens, a beam splitter, a second lens and a third lens, wherein the first lens is provided in a radiation path of spontaneous radiation of the chip to be tested, the beam splitter is provided in an exit direction of the first lens, the beam splitter is configured to split emergent light from the first lens into two beams, and the second lens and the third lens are provided in two exit directions of the beam splitter respectively;
a spectrometer, comprising a signal collection element, wherein the signal collection element of the spectrometer is provided in an exit direction of the second lens;
a CCD camera, provided in an exit direction of the third lens;
a two-dimensional displacement device, on which the lens device, the signal collection element of the spectrometer and the CCD camera are provided, wherein the two-dimensional displacement device is capable of driving the lens device, the signal collection element of the spectrometer and the CCD camera to move, so as to change the relative position between the first lens and the chip to be tested without changing a perpendicular distance between the first lens and an exit surface of the spontaneous radiation of the chip to be tested.

In the method for performance evaluation and structure optimization of a high-power semiconductor laser chip provided by the present application, by setting a window in an N-surface electrode of a chip to be tested and imaging through a lens, the quantum well of the chip to be tested can be imaged at a position outside the chip to be tested, so as to get the temperature distribution and the carrier concentration distribution of the chip to be tested in the operating state. Therefore, without adversely affecting the performance of the chip, it can get the temperature distribution and the carrier concentration distribution of the chip to be tested in the operating state with a resolution that is freely adjustable, the operation is convenient and easy to implement, the inference procedure in the evaluation process is reduced, and the evaluation results are more accurate. At the same time, according to the results of the carrier concentration distribution test, mismatch between the carrier distribution and the light field distribution in the longitudinal direction is eliminated by increasing the number of segments of the N-surface electrode and changing an arrangement of gold wires on each segment of the N-surface electrode, thereby improving the performance of the chip to be tested.

### BRIEF DESCRIPTION OF THE DRAWINGS

FIG. 1 is a flow chart of a method for performance evaluation of a high-power semiconductor laser chip provided in an embodiment of the present application.

FIG. 2 is a partial schematic diagram of a cross-section of the chip to be tested in the light-emitting direction in the method for performance evaluation of a high-power semiconductor laser chip provided in an embodiment of the present application.

FIG. 3 is a structural schematic diagram of a system for performance evaluation of a high-power semiconductor laser chip provided in an embodiment of the present application.

FIG. 4 is a schematic diagram of a cross-section of an N-surface electrode in the cavity length direction in the method for performance evaluation of a high-power semiconductor laser chip provided in an embodiment of the present application.

FIG. 5 is an arrangement of gold wires of a conventional high-power semiconductor laser chip.

FIG. 6 shows a schematic diagram of carrier distribution and light field distribution in the longitudinal direction of a conventional high-power semiconductor laser chip.

FIG. 7 is an arrangement of gold wires of a high-power semiconductor laser chip that has been optimized by a method for structure optimization of a high-power semiconductor laser chip provided in an embodiment of the present application.

FIG. 8 is a schematic diagram of carrier distribution and light field distribution in the longitudinal direction of a high-power semiconductor laser chip that has been optimized by the method for structure optimization of a high-power semiconductor laser chip provided in an embodiment of the present application.

### DETAILED DESCRIPTION

In order to make the purpose, technical solutions and advantages of the present application more clearly understood, the present application is hereinafter described in further detail with reference to the drawings and embodiments. It should be understood that the specific embodiments described herein only represent a part of the embodiments of the present application, not all of them, and are only used to explain the present application and are not intended to limit the present application. Based on the embodiments described in the present application, all other embodiments obtainable by a person with ordinary skill in the art without making creative labor fall within the protection scope of the present application.

In the description of the present application, it needs to be noted that orientations or positional relationships indicated by the terms such as “center”, “up”, “down”, “left”, “right”, “front”, “back”, “vertical”, “horizontal”, “inside”, “outside”, “ends”, “sides”, “bottom”, “top”, and etc., are based on those shown in the drawings, and are intended only to facilitate the description of the present application and to simplify the description, and are not intended to indicate or imply that elements referred to must have a particular orientation or must be constructed and operated in a particular orientation, and therefore is not to be understood as a limitation to the present application. Furthermore, the terms such as “first”, “second”, “superior”, “inferior”, “primary”, “secondary”, and etc., are used for descriptive purposes only and may simply be used to distinguish different components more clearly, and are not to be understood as indicating or implying relative importance.

In the description of the present application, it needs to be noted that, unless otherwise expressly specified and limited, the terms ‘mount’, “connecting”, ‘connection’ are to be understood in a broad sense, e.g., as a fixed connection or as a detachable connection, an integral connection, a mechanical connection, an electrical connection, a direct connection, an indirect connection through an intermediate medium, or an internal communication of two elements. For a person with ordinary skill in the art, the specific meaning of the above terms in the present application can be understood according to specific situations.

Furthermore, the technical features involved in different embodiments of the present application described below may be combined with each other as long as they do not constitute a conflict with each other.

### Embodiment 1

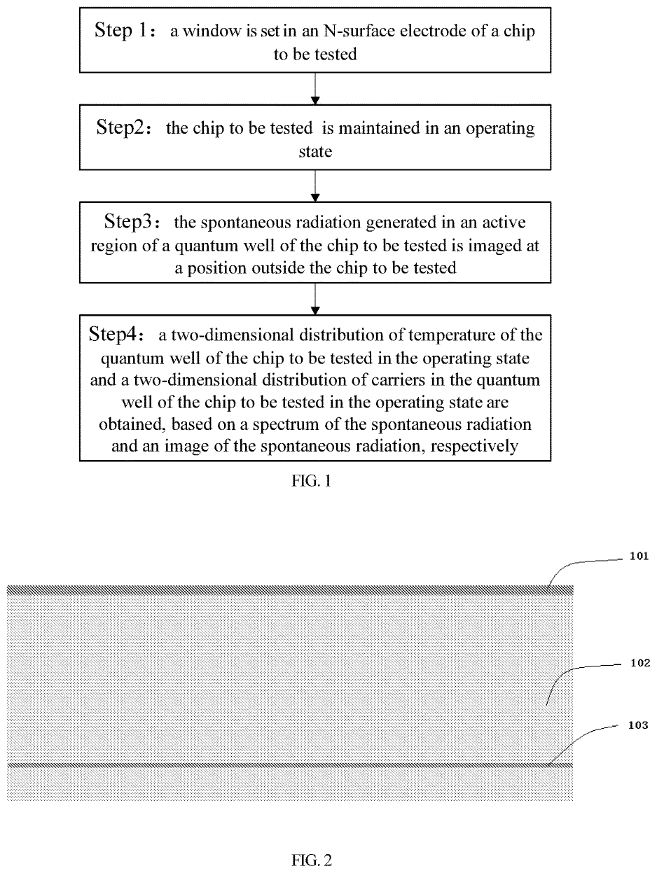

Referring to FIG. 1 of the appended Drawings, an embodiment of the present application provides a method for performance evaluation of a high-power semiconductor laser chip that comprises the following steps:
Step 1: a window is set in an N-surface electrode of a chip to be tested;
Step 2: the chip to be tested is maintained in an operating state;
Step 3: the spontaneous radiation generated in an active area of a quantum well of the chip to be tested is imaged at a position outside of the chip to be tested;
Step 4: a two-dimensional distribution of temperature of the quantum well of the chip to be tested in the operating state and a two-dimensional distribution of carriers in the quantum well of the chip to be tested in the operating state are obtained, based on a spectrum of the spontaneous radiation and an image of the spontaneous radiation, respectively.

Specifically, referring to FIG. 2 of the specification, a partial schematic diagram of a cross-section of the chip to be tested in the light-emitting direction is shown. The structure shown in the figure includes an N-surface electrode 101, a substrate 102, and a quantum well 103.

The present embodiment illustrates a method for performance evaluation of a high-power semiconductor laser chip by taking as an example a GaAs-based chip to be tested with a width of an injection area being 90 μm, a reflectivity of a front cavity being 1.5%, a reflectivity of a back cavity being 99%, and a cavity length being 5.0 mm.

In an optional embodiment, in step 1, the window may be set in the N-surface electrode of the chip to be tested by a lift-off process. Thereby, a window is set in the N-surface electrode of the chip to be tested, so that spontaneous radiation of the quantum well of the chip to be tested in the operating state can be imaged in a path through the substrate.

The window set in the N-surface electrode of the chip to be tested should fulfill a condition of not significantly affecting the electrical injection. In an optional embodiment, the size of the window needs to satisfy the following formula:

1≤0.01*L; wherein l represents a size of the window in a cavity length direction, and L represents a cavity length of the chip to be tested.

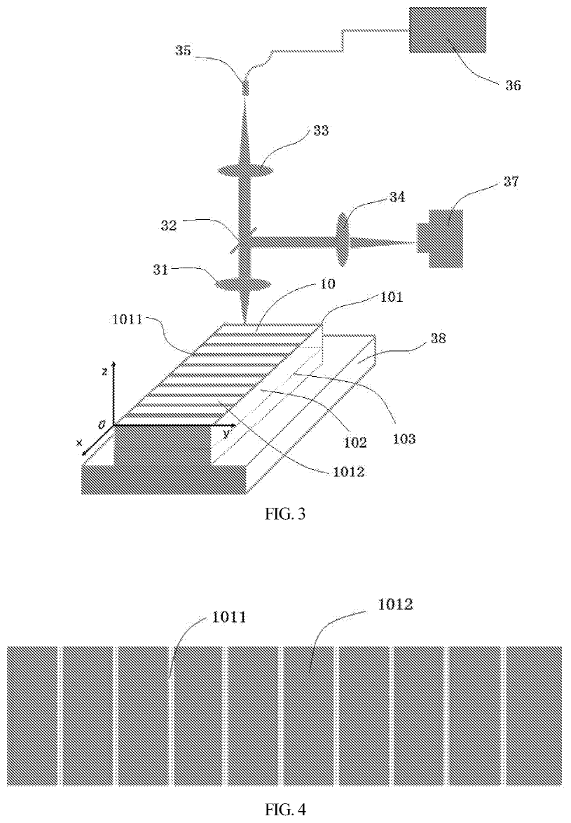

Referring to FIG. 3 of the appended Drawings, a structural schematic diagram of a system for performance evaluation of a high-power semiconductor laser chip is shown. For ease of description, a three-dimensional coordinate system is established with one vertex of an exit surface of the spontaneous radiation of the chip 10 to be tested as the origin O, an exit direction of the spontaneous radiation as the z-axis, and a light-emitting direction of the chip 10 to be tested as the x-axis.

The chip 10 to be tested is placed on a thermostat device 38, the thermostat device 38 is configured to maintain a temperature of the chip 10 to be tested so that the chip to be tested 10 are able to operate at a predetermined temperature, a first lens 31, a beam splitter 32, a second lens 33, a third lens 34, a signal collection element 35 of a spectrometer 36, and a CCD camera 37 are all provided on a two-dimensional displacement device (not shown in the figure), and the first lens 31, the beam splitter 32, the second lens 33, the third lens 34, the signal collection element 35 of the spectrometer 36 and the CCD camera 37 are fixed in their relative positions and are capable of moving in the XY plane as driven by the two-dimensional displacement device.

When z=0, a schematic diagram of a cross-section in the xy-plane, i.e., a schematic diagram of a cross-section of the N-surface electrode in the cavity length direction can be shown by referring to FIG. 4 of the appended Drawings, and the N-surface electrode 101 comprises windows 1011 and metal areas 1012. Taking the cavity length being 5.0 mm as an example, the size of each window may be 50 μm*400 μm, and the positions of the windows are uniformly distributed along the cavity length direction at spacing intervals of 500 μm.

In step 2, the chip to be tested is maintained in an operating state, a purpose of which is, to cause spontaneous radiation to be generated in an active area of a quantum well of the chip to be tested.

In step 3, the spontaneous radiation is imaged at a position outside the chip to be tested by using a first lens pre-set in a radiation path of the spontaneous radiation, specifically comprising:
providing a beam splitter in an exit direction of the first lens, providing a second lens and a third lens in two exit directions of the beam splitter respectively, providing a signal collection element of the spectrometer in an exit direction of the second lens, and providing a CCD camera in an exit direction of the third lens.

As a result, the beam splitter, the second lens and the third lens are set, so that the spontaneous radiation generated in the active area of the quantum well of the chip to be tested in the operating state can be imaged onto both the signal collection element of the spectrometer and the CCD camera at the same time through the first lens, the beam splitter, the second lens and the third lens, which facilitates the calculation of the temperature distribution and the carrier distribution of the quantum well.

In step 4, a two-dimensional distribution of temperature of the quantum well of the chip to be tested in the operating state and a two-dimensional distribution of carriers in the quantum well of the chip to be tested in the operating state are obtained, based on a spectrum of the spontaneous radiation and an image of the spontaneous radiation, respectively, specifically comprising:
acquiring, by using a spectrometer outside the chip to be tested, a spectrum of the spontaneous radiation to obtain a two-dimensional distribution of temperature of the quantum well of the chip to be tested in the operating state; and
acquiring, by using a CCD camera outside the chip to be tested, an image of the spontaneous radiation to obtain a two-dimensional distribution of carriers in the quantum well of the chip to be tested in the operating state.

Wherein, the two-dimensional distribution of temperature of the quantum well of the chip to be tested in the operating state is obtained specifically by the following steps:
maintaining an injection current I of the chip to be tested unchanged, maintaining a temperature T0 of the chip to be tested unchanged, maintaining relative positions of the signal collection element of the spectrometer, the CCD camera, the first lens, the beam splitter, the second lens, and the third lens unchanged, maintaining a perpendicular distance between the first lens and an exit surface of the spontaneous radiation of the chip to be tested unchanged, moving the two-dimensional displacement device in a plane so as to change the relative position between the first lens and the chip to be tested, and recording data of the spectrometer in sequence for each spatial position to obtain spectral peak wavelength λ(T0) of the spontaneous radiation in the window of the chip to be tested that is operating at the injection current I and the temperature T0;
under a condition of satisfying predetermined requirements of duty ratio and pulse duration, changing the temperature of the chip to be tested so that the temperature of the chip to be tested are respectively set at T1, T2, Tn−1, and Tn, where n is a natural number not less than 2, and the T1, T2, Tn−1, and Tn have different values in units of ° C.; and under temperature conditions of T1, T2, . . . . Tn−1 and Tn, respectively, maintaining relative positions of the signal collection element of the spectrometer, the first lens, the beam splitter and the second lens unchanged, and changing a horizontal distance between the signal collection element of the spectrometer and the chip to be tested, that is, maintaining a perpendicular distance between the first lens and the exit surface of the spontaneous radiation of the chip to be tested unchanged, and changing the relative position between the first lens and the chip to be tested, and recording data of the spectrometer in sequence for each spatial position so as to respectively obtain spectral peak wavelengths λ(T1), λ(T2) . . . λ(Tn−1) and λ(Tn) of the spontaneous radiation in the window of the chip to be tested that is operating at different temperatures;
calculating a spectral temperature drift coefficient δλof the spontaneous radiation by using least squares linear regression; and
according to the spectral temperature drift coefficient δλof the spontaneous radiation and the spectral peak wavelength λ(T0), obtaining a two-dimensional distribution of temperature of the quantum well of the chip to be tested that is operating at the injection current I and the temperature T0.

Specifically, the signal collection element of the spectrometer may be an optical fiber, wherein the optical fiber collects light generated by the spontaneous radiation from the chip to be tested and inputs the obtained light into the spectrometer, so as to obtain the spectral distribution of the spontaneously radiated light.

The temperature T0 and the injection current I are pre-set parameters, the injection current I is realized by applying an external power supply onto the chip to be tested, and the temperature T0 is realized by the thermostat device, wherein the value of the temperature T0 can be randomly selected under a premise of being able to ensure normal operation of the chip to be tested. The thermostatic device may be any device in the prior art that can maintain the chip to be tested in a preset temperature range by automatically opening a circuit or closing a circuit, and the thermostatic device may comprise a temperature-sensitive element and a converter, wherein the temperature-sensitive element is configured to measure changes in temperature, and the converter is configured to heat up or dissipate heat for the chip to be tested according to the changes in temperature.

The predetermined requirements of duty ratio and pulse duration may be a low duty ratio and a short pulse duration, wherein a low duty ratio means a duty ratio of one thousandth and a short pulse duration means a pulse width of less than 1 μs.

Of the temperatures T1, T2, T3, . . . Tn−1, and Tn, a value of n may be a natural number greater than 2. When n=8, the temperatures T1, T2, T3, . . . , T7 and T8 may be an arithmetic sequence with an initial value of 5° C. and a step size of 5° C., or may be an arithmetic sequence with an initial value of 4° C. and a step size of 7° C., or may be eight randomly selected values of temperature points under the premise of ensuring the normal operation of the chip to be tested. As a result, the spectral temperature drift coefficient δλof the spontaneous radiation is calculated more accurately by multiple times of measurements, thereby reducing errors that may exist in a single time of measurement.

By changing the radiator temperature T for n times, n sets of spectral peak wavelengths λ(Tn) of spontaneous radiation corresponding thereto are obtained, and the spectral temperature drift coefficient 82 is obtained by substituting these n sets of observed data into the least squares formula.

The formula for calculating the spectral temperature drift coefficient 82 is as follows:

$$δ λ = \frac{{\sum }_{i = 1}^{n} ( {λ}_{i} - \overline{λ} ) ( {T}_{i} - \overline{T} )}{{\sum }_{i = 1}^{n} {( {T}_{i} - \overline{T} )}^{2}}$$

wherein λi represents the spectral peak wavelength of spontaneous radiation obtained in the ith measurement. Ti represents a temperature corresponding to the ith measurement, and i is a natural number not less than 1; λ̅ represents an average value of the spectral peak wavelengths in the n times of measurements, and T̅ represents an average value of the temperatures in the n times of measurements.

In an optional embodiment, according to the spectral temperature drift coefficient δλ of the spontaneous radiation and the spectral peak wavelength λ(T0) corresponding to the temperature T0, a two-dimensional distribution of temperature of the quantum well of the chip to be tested that is operating at the injection current I and the temperature T0 is obtained, specifically by using the following formula:

$${T}_{c} = δ λ * ( λ - λ ( T 0 ) ) + T 0$$

wherein Tc represents a temperature of the quantum well, λ is the current value of spectral peak wavelength obtained from the spectrometer, and λ(T0) represents the spectral peak wavelength λ(T0) obtained when the temperature is T0.

In an optional embodiment, the step of acquiring, by using a CCD camera outside the chip to be tested, an image of the spontaneous radiation to obtain a two-dimensional distribution of carriers in the quantum well of the chip to be tested in the operating state may comprise:
maintaining the injection current I of the chip to be tested unchanged, maintaining the temperature T0 of the chip to be tested unchanged, maintaining the relative positions of the signal collection element of the spectrometer, the CCD camera, the first lens, the beam splitter, the second lens, and the third lens unchanged, maintaining the perpendicular distance between the first lens and the exit surface of the spontaneous radiation of the chip to be tested unchanged, and acquiring a CCD image of the spontaneous radiation;
obtaining a gray value of the CCD image, performing square root calculation on the gray value, so as to obtain a two-dimensional distribution of carriers in the quantum well of the chip to be tested that is operating at the injection current I and the temperature T0.

Since a field of view of the CCD camera is sufficiently large, all CCD images that are needed for the spontaneous radiation imaging can be obtained by acquiring a CCD image for once at an initial position of the CCD camera or at an arbitrary position during movement of the CCD camera along with the two-dimensional displacement device. Since an intensity of the spontaneous radiation is directly proportional to a square of the carrier concentration, the carrier distribution can be characterized by a square root of a grey value of the CCD image, which is a simple test method, easy to calculate, and the calculation results are more accurate.

In the method for performance evaluation of a high-power semiconductor laser chip provided by the present application, by setting a window in an N-surface electrode of a chip to be tested and imaging through a lens, the quantum well of the chip to be tested can be imaged at a position outside the chip to be tested, so as to get the temperature distribution and the carrier concentration of the chip to be tested in the operating state. Therefore, without adversely affecting the performance of the chip, it can get the temperature distribution and the carrier concentration distribution of the chip to be tested in the operating state with a resolution that is freely adjustable, the operation is convenient and easy to implement, the inference procedure in the evaluation process is reduced, and the evaluation results are more accurate. The evaluation of temperature distribution and carrier concentration distribution is the basis for evaluating the lateral thermal lensing effect and the longitudinal temperature non-uniformity effect, as well as the basis for suppressing the effects of lateral carrier accumulation, lateral carrier leakage, and longitudinal carrier non-uniformity, thereby being beneficial for the subsequent evaluation and optimization of the chip to be tested.

### Embodiment 2

An embodiment of the present application provides a method for structure optimization of a high-power semiconductor laser chip that comprises the following steps:
obtaining a carrier distribution of the chip to be tested and a light field distribution of the chip to be tested, and recording a current value of the number of longitudinal segments of an N-surface electrode of the chip to be tested as W;
normalizing the light field distribution of the chip to be tested to obtain a normalized light field intensity, recorded as P(z);
normalizing the carrier distribution of the chip to be tested to obtain a normalized carrier intensity, recorded as N(z);
calculating a mismatch degree δ based on the normalized carrier intensity N(z) and the longitudinal normalized distribution P(z) of the normalized light field intensity, wherein an expression formula of the mismatch degree δ is as follows:

$$δ = {\int }_{0}^{1} ( N ( z ) - P ( z ) ) dz$$

where z represents a normalized longitudinal position:
determining whether the chip to be tested needs to be optimized according to a current value of the mismatch degree δ, and if it is determined that the chip to be tested needs to be optimized, increasing the number of segments of the N-surface electrode of the chip to be tested, so that W=W+1, and changing an arrangement of gold wires on each segment of the N-surface electrode, so that the number of gold wires on each segment of the N-surface electrode is directly proportional to the normalized light field intensity on each segment;
repeatedly performing the above steps until it is determined that the chip to be tested does not need to be optimized according to the mismatch degree δ, and ending the optimization;
wherein the carrier distribution of the chip to be tested is obtained by the method for performance evaluation of a high-power semiconductor laser chip according to any example of Embodiment 1.

As a result, by increasing the number of segments of the N-surface electrode, an injection current injected into each segment is changed, the adjustment precision is increased, and an arrangement of gold wires can be changed in a more refined manner; by changing the number of gold wires on each segment so as to change the arrangement of gold wires, the carrier distribution is adjusted, the difference between the carrier distribution and the light field distribution is reduced, and the light field distribution and the carrier distribution are caused to approach each other towards coinciding, thereby achieving an optimization effect.

The initial value of the number W of segments of the N-surface electrode may be 1 or a natural number greater than 1.

For the chip to be tested that has a given reflectivity of its cavity surface, the light field distribution thereof is fixed.

Specifically, the step of determining whether the chip to be tested needs to be optimized according to the current value of the mismatch degree δ comprises:
calculating a value of the following formula:

$$\frac{\vert δ \vert}{1 - {\int }_{0}^{1} P ( z ) dz}$$

wherein δ represents the mismatch degree and P(z) represents the normalized light field intensity P(z); and
determining whether the calculated value is less than a predetermined value, and if the calculated value is less than the predetermined value, the chip to be tested does not need to be optimized, and if the calculated value is not less than the predetermined value, the chip to be tested needs to be optimized.

In an optional embodiment, the predetermined value may be 5%. Thereby, when the calculated value is less than 5%, it can be regarded as the light field distribution and the carrier distribution roughly coinciding, and the predetermined value may be set according to the needs in actual production.

Increasing the number of segments of the N-surface electrode of the chip to be tested can be achieved by means of metal stripping.

Specifically, referring to FIG. 5 of the appended Drawings, an arrangement of gold wires of a conventional high-power semiconductor laser chip is shown, and FIG. 6 of the appended Drawings shows a schematic diagram of carrier distribution and light field distribution in the longitudinal direction of a conventional high-power semiconductor laser chip. For the conventional high-power semiconductor laser chip, the number of segments of the N-surface electrode is 1, an arrangement of gold wires on the N-surface electrode is uniform, the number of gold wires per unit length is equal, and the carriers are injected uniformly along the cavity length, however, the light field is asymmetric due to asymmetry of the front and back cavity surface coatings, resulting in extreme asymmetry of the distribution of the light field along the cavity length. Thus, there is a serious mismatch between the carrier distribution and the light field distribution, resulting in a decrease in device efficiency, an increase in heat generation, and an increase in temperature.

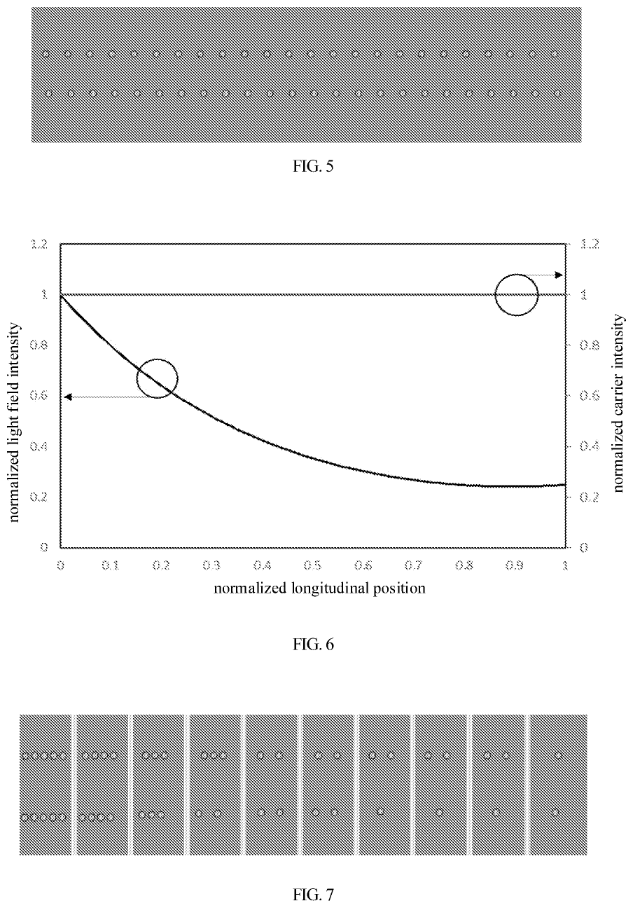

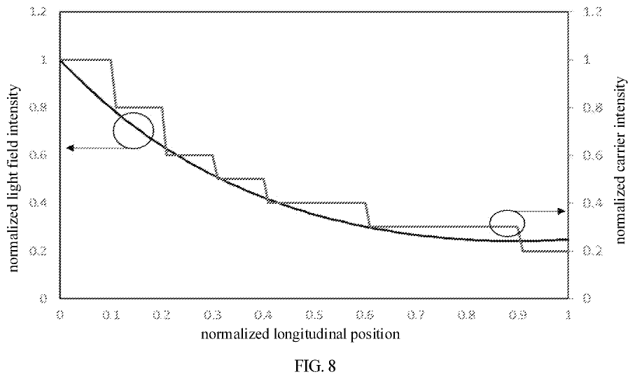

FIG. 7 of the appended Drawings shows an arrangement of gold wires of a high-power semiconductor laser chip that has been optimized by a method for structure optimization of a high-power semiconductor laser chip provided in an embodiment of the present application, and FIG. 8 of the appended Drawings shows a schematic diagram of carrier distribution and light field distribution in the longitudinal direction of a high-power semiconductor laser chip that has been optimized by the method for structure optimization of a high-power semiconductor laser chip provided in an embodiment of the present application. In FIG. 6 of the appended Drawings and FIG. 8 of the appended Drawings, a meaning represented by each curve is schematically shown by a direction of an arrow. As can be seen from FIG. 7 of the appended Drawings, the greater the normalized light field intensity, the greater the number of gold wires arranged within the corresponding segment.

The features of the present embodiment that are the same as those of Embodiment 1 are not repeated herein.

In the method for structure optimization of a high-power semiconductor laser chip provided by the embodiments of the present application, by introducing a mismatch degree, the degree of coincidence between the carrier distribution and the light field distribution is judged, and by gradually increasing the number of segments of the N-surface electrode and changing the number of gold wires on each segment, the difference between the light field distribution and the carrier distribution is reduced, so that, in one aspect, an efficiency of the chip is effectively improved and at the same time the heat generation of the chip is reduced, and in another aspect, since the more the number of segments, the more the process steps, the cyclic steps of increasing the number of segments, changing the arrangement of gold wires, calculating the mismatch degree, and then increasing the number of segments again, changing the arrangement of gold wires again, can prevent unnecessary process steps at the same time of making the mismatch degree satisfies the preset condition, thereby improving the efficiency of the optimization at the same time of ensuring the effect of the optimization.

### Embodiment 3

Referring to FIG. 3 of the appended Drawings, the embodiments of the present application also provide a system for performance evaluation of a high-power semiconductor laser chip, applying the method for performance evaluation of a high-power semiconductor laser chip according to any example of Embodiment 1, and the system comprises:
a thermostatic device 38, configured to maintain a temperature of the chip to be tested so that the chip to be tested is able to operate at a predetermined temperature;
a lens device, comprising a first lens 31, a beam splitter 32, a second lens 33 and a third lens 34, wherein the first lens 31 is provided in a radiation path of spontaneous radiation of the chip 10 to be tested, the beam splitter 32 is provided in an exit direction of the first lens 31, the beam splitter 32 is configured to split emergent light from the first lens 31 into two beams, and the second lens 33 and the third lens 34 are provided in two exit directions of the beam splitter 32 respectively:
a spectrometer 36, comprising a signal collection element 35, wherein the signal collection element 35 of the spectrometer 36 is provided in an exit direction of the second lens 33;
a CCD camera 37, provided in an exit direction of the third lens 34;
a two-dimensional displacement device, on which the lens device, the signal collection element 35 of the spectrometer 36 and the CCD camera 37 are provided, wherein the two-dimensional displacement device is capable of driving the lens device, the signal collection element 35 of the spectrometer 36 and the CCD camera 37 to move, so as to change the relative position between the first lens 31 and the chip to be tested 10 without changing a perpendicular distance between the first lens 31 and an exit surface of the spontaneous radiation of the chip 10 to be tested.

In an optional embodiment, the second lens 33 and the third lens 34 use lenses with the same parameters, and a distance between the signal collection element 35 of the spectrometer and the second lens 33 is equal to a distance between the CCD camera 37 and the third lens 34.

The features of the present embodiment that are the same as those of Embodiment 1 are not repeated herein.

In the system for performance evaluation of a high-power semiconductor laser chip provided by the present application, by setting a window in an N-surface electrode of a chip to be tested and imaging through a lens, the quantum well of the chip to be tested can be imaged at a position outside the chip to be tested, so as to get the temperature distribution and the carrier concentration of the chip to be tested in the operating state. Therefore, without adversely affecting the performance of the chip, it can get the temperature distribution and the carrier concentration distribution of the chip to be tested in the operating state with a resolution that is freely adjustable, the operation is convenient and easy to implement, the inference procedure in the evaluation process is reduced, and the evaluation results are more accurate.

The foregoing is only optional embodiments of the present application, and it should be noted that, for a person with ordinary skill in the art, on the premise of not departing from the principles of the present application, some variations and modifications may be made, and these variations and modifications shall be considered to be within the protection scope of the present application.

1. A method for performance evaluation of a high-power semiconductor laser chip, comprising:
setting a window in an N-surface electrode of a chip to be tested;
maintaining the chip to be tested in an operating state, wherein spontaneous radiation is generated in an active area of a quantum well of the chip to be tested;
imaging the spontaneous radiation at a position outside the chip to be tested by using a first lens pre-set in a radiation path of the spontaneous radiation;
acquiring, by using a spectrometer outside the chip to be tested, a spectrum of the spontaneous radiation to obtain a two-dimensional distribution of temperature of the quantum well of the chip to be tested in the operating state; and
acquiring, by using a CCD camera outside the chip to be tested, an image of the spontaneous radiation to obtain a two-dimensional distribution of carriers in the quantum well of the chip to be tested in the operating state;
wherein the step of imaging the spontaneous radiation at a position outside the chip to be tested by using a first lens pre-set in a radiation path of the spontaneous radiation comprises:
providing a beam splitter in an exit direction of the first lens, providing a second lens and a third lens in two exit directions of the beam splitter respectively, providing a signal collection element of the spectrometer in an exit direction of the second lens, and providing the CCD camera in an exit direction of the third lens;
wherein the step of acquiring, by using a spectrometer outside the chip to be tested, a spectrum of the spontaneous radiation to obtain a two-dimensional distribution of temperature of the quantum well of the chip to be tested in the operating state comprises:
maintaining an injection current I of the chip to be tested unchanged, maintaining a temperature T0 of the chip to be tested unchanged, maintaining relative positions of the signal collection element of the spectrometer, the CCD camera, the first lens, the beam splitter, the second lens, and the third lens unchanged, maintaining a perpendicular distance between the first lens and an exit surface of the spontaneous radiation of the chip to be tested unchanged, changing the relative position between the first lens and the chip to be tested, and recording data of the spectrometer in sequence to obtain spectral peak wavelength λ(T0);
under a condition of satisfying predetermined requirements of duty ratio and pulse duration, changing the temperature of the chip to be tested so that the temperature of the chip to be tested are respectively set at T1, T2, . . . , Tn−1, and Tn, where n is a natural number not less than 2, and the T1, T2, Tn−1, and Tn have different values in units of ° C.; and under temperature conditions of T1, T2, . . . , Tn−1 and Tn, respectively, maintaining relative positions of the signal collection element of the spectrometer, the first lens, the beam splitter and the second lens unchanged, changing a horizontal distance between the signal collection element of the spectrometer and the chip to be tested, and recording data of the spectrometer in sequence to obtain spectral peak wavelengths λ(T1), λ(T2), . . . , λ(Tn−1) and λ(Tn);
calculating a spectral temperature drift coefficient δλ of the spontaneous radiation by using least squares linear regression; and
according to the spectral temperature drift coefficient δλ of the spontaneous radiation and the spectral peak wavelength λ(T0), obtaining a two-dimensional distribution of temperature of the quantum well of the chip to be tested that is operating at the injection current I and the temperature T0.

2. The method for performance evaluation of a high-power semiconductor laser chip according to claim 1, wherein the window is set in the N-surface electrode of the chip to be tested by a lift-off process.

3. The method for performance evaluation of a high-power semiconductor laser chip according to claim 1, wherein the size of the window satisfies the following formula:
$$l \leq 0.01 * L ;$$
wherein, l represents a size of the window in a cavity length direction, and L represents a cavity length of the chip to be tested.

4. The method for performance evaluation of a high-power semiconductor laser chip according to claim 1, wherein the step of acquiring, by using a CCD camera outside the chip to be tested, an image of the spontaneous radiation to obtain a two-dimensional distribution of carriers in the quantum well of the chip to be tested in the operating state comprises:
maintaining the injection current I of the chip to be tested unchanged, maintaining the temperature T0 of the chip to be tested unchanged, maintaining the relative positions of the signal collection element of the spectrometer, the CCD camera, the first lens, the beam splitter, the second lens, and the third lens unchanged, maintaining the perpendicular distance between the first lens and the exit surface of the spontaneous radiation of the chip to be tested unchanged, and acquiring a CCD image of the spontaneous radiation;
obtaining a gray value of the CCD image, performing square root calculation on the gray value, so as to obtain a two-dimensional distribution of carriers in the quantum well of the chip to be tested that is operating at the injection current I and the temperature T0.

5. A method for structure optimization of a high-power semiconductor laser chip, wherein the method comprises:
obtaining a carrier distribution of the chip to be tested and a light field distribution of the chip to be tested, and recording a current value of the number of longitudinal segments of an N-surface electrode of the chip to be tested as W;
normalizing the light field distribution of the chip to be tested to obtain a normalized light field intensity, recorded as P(z);
normalizing the carrier distribution of the chip to be tested to obtain a normalized carrier intensity, recorded as N(z);
calculating a mismatch degree δ based on the normalized carrier intensity N(z) and the normalized light field intensity P(z), wherein an expression formula of the mismatch degree δ is as follows:
$$δ = {\int }_{0}^{1} ( N ( z ) - P ( z ) ) dz$$
where z represents a normalized longitudinal position;
determining whether the chip to be tested needs to be optimized according to a current value of the mismatch degree δ, and if it is determined that the chip to be tested needs to be optimized, increasing the number of segments of the N-surface electrode of the chip to be tested, so that W=W+1, and changing an arrangement of gold wires on each segment of the N-surface electrode, so that the number of gold wires on each segment of the N-surface electrode is directly proportional to the normalized light field intensity on each segment;
repeatedly performing the above steps until it is determined that the chip to be tested does not need to be optimized according to the mismatch degree δ, and ending the optimization;
wherein the carrier distribution of the chip to be tested is obtained by the method for performance evaluation of a high-power semiconductor laser chip according to claim 1.

6. The method for structure optimization of the high-power semiconductor laser chip according to claim 5, wherein the step of determining whether the chip to be tested needs to be optimized according to the current value of the mismatch degree δ comprises:
calculating a value of the following formula:
$$\frac{\vert δ \vert}{1 - {\int }_{0}^{1} P ( z ) dz}$$
wherein δ represents the mismatch degree and P(z) represents the normalized light field intensity P(z); and
determining whether the calculated value is less than a predetermined value, and if the calculated value is less than the predetermined value, the chip to be tested does not need to be optimized, and if the calculated value is not less than the predetermined value, the chip to be tested needs to be optimized.

7. A system for performance evaluation of a high-power semiconductor laser chip, applying the method for performance evaluation of a high-power semiconductor laser chip according to claim 1, wherein the system comprises:
a thermostatic device, configured to maintain a temperature of the chip to be tested so that the chip to be tested is able to operate at a predetermined temperature;
a lens device, comprising a first lens, a beam splitter, a second lens and a third lens, wherein the first lens is provided in a radiation path of spontaneous radiation of the chip to be tested, the beam splitter is provided in an exit direction of the first lens, the beam splitter is configured to split emergent light from the first lens into two beams, and the second lens and the third lens are provided in two exit directions of the beam splitter respectively;
a spectrometer, comprising a signal collection element, wherein the signal collection element of the spectrometer is provided in an exit direction of the second lens;
a CCD camera, provided in an exit direction of the third lens;
a two-dimensional displacement device, on which the lens device, the signal collection element of the spectrometer and the CCD camera are provided, wherein the two-dimensional displacement device is capable of driving the lens device, the signal collection element of the spectrometer and the CCD camera to move, so as to change the relative position between the first lens and the chip to be tested without changing a perpendicular distance between the first lens and an exit surface of the spontaneous radiation of the chip to be tested.

8. The system for performance evaluation of a high-power semiconductor laser chip according to claim 7, wherein the second lens and the third lens use lenses with the same parameters, and a distance between the signal collection element of the spectrometer and the second lens is equal to a distance between the CCD camera and the third lens.
